(19) United States
(12) Patent Application Publication
(10) Pub. No.: US 2026/0239701 A1
(43) Pub. Date: Aug. 13, 2026

(54) Multi-Substrate Wafer with Radially Grown Substrates

(71) Applicant: Zadient Technologies SAS, Sainte-Hélène-du Lac (FR)

(72) Inventors: Kagan Ceran, Saint Baldoph (FR); Jan Richter, Dresden (DE); Friedrich Schaaff, Halle (DE)

(21) Appl. No.: 19/469,883

(22) PCT Filed: Mar. 25, 2024
(86) PCT No.: PCT/EP2024/057950

§ 371 Date: Sep. 26, 2025

(30) Foreign Application Priority Data
Mar. 28, 2023 (WO) PCT/EP2023/057972
May 17, 2023 (WO) PCT/EP2023/063308

(51) Int. Cl. H10D 62/834; H10D 62/832; H10P 10/00; H10P 14/20; H10P 30/20

(52) U.S. Cl. CPC H10D 62/834; H10D 62/8325; H10P 10/128; H10P 14/274; H10P 30/2042

(57) ABSTRACT

The present invention refers to a multi-substrate wafer. Said multi-substrate wafer includes at least a first substrate and a second substrate. The first substrate and the second substrate are bonded together and the first substrate is a monocrystalline SiC crystal. The second substrate includes polycrystalline 3C—SiC and at least 30% [volume] of the polycrystalline 3C—SiC is grown in a radial direction around at least one or exactly one central element. The central element preferably includes or consists of SiC. The second substrate has a specific electrical resistance of less than 15 mOhm-cm. The second substrate is at least nitrogen doped and more than 10¹⁸ nitrogen atoms per cm³ are present inside the second substrate due to doping.

### CROSS REFERENCE TO RELATED APPLICATIONS

This application is a § 371 national stage of international application no. PCT/EP2024/057950, filed on Mar. 25, 2024, which claims priority to international application no. PCT/EP2023/063308, filed on May 17, 2023, which claims priority to international application no. PCT/EP2023/057972, filed on Mar. 28, 2023, which claims priority to European application no. 22173970.9, filed on May 18, 2022, the entire contents of all of which are hereby incorporated by reference herein.

### FIELD

The present invention refers according to claim 1 to a multi-substrate wafer, according to claim 14 to a method for the production of a compound wafer and according to claim 21 and 22 to an electronic device.

### BACKGROUND

Technological background is disclosed e.g. by JP2009117533A, US2010/291328A1 and WO2022/123078A1.

It is common practice to grow a polycrystalline SiC carrier wafer by means of epitaxy and bond it with a monocrystalline SiC wafer to form a composite wafer.

However, such composite wafers are expensive and do not provide a high-quality starting point for further processing.

### SUMMARY

It is the object of the present invention to provide a beneficial composite wafer, a method for the production of such a beneficial composite wafer and an electronic device produced on or as part of the beneficial composite wafer.

The present invention is solved by a composite wafer or multi-substrate wafer according to claim 1. The composite wafer or multi-substrate wafer according to the present invention preferably at least comprises a first substrate and a second substrate, wherein the first substrate and the second substrate are bonded together. The first substrate is a monocrystalline SiC crystal. The second substrate comprises, in particular consists of, polycrystalline SiC, in particular polycrystalline 3C—SiC, wherein more than 90% [volume], in particular more than 95% [volume] and preferably more than 99% [volume] and most preferably more than 99,9% [volume], of the second substrate is polycrystalline SiC or wherein more than 90% [mass], in particular more than 95% [mass] and preferably more than 99% [mass] and most preferably more than 99,9% [mass], of the second substrate is polycrystalline SiC. The polycrystalline SiC of the second substrate preferably comprises more than 50% [volume], in particular more than 75% [volume] and preferably more than 90% [volume] and most preferably more than 95% [volume], polycrystalline 3C—SiC or the polycrystalline SiC of the second substrate preferably comprises more than 50% [mass], in particular more than 75% [mass] and preferably more than 90% [mass] and most preferably more than 95% [mass], polycrystalline 3C—SiC. Preferably at least 30% [volume], in particular at least 50% [volume] and preferably at least 70% [volume], of the polycrystalline SiC, in particular polycrystalline 3C—SiC, is grown in radial direction around respectively surrounding at least one or exactly one central element, wherein the central element preferably comprises or consists of SiC. The second substrate preferably has a specific electrical resistance of less than 30 mOhmcm, in particular of less than 15 mOhmcm or less than 10 mOhmcm or preferably less than 5 mOhmcm or most preferably less than 3 mOhmcm. Additionally, or alternatively the second substrate can be doped, in particular nitrogen doped. Preferably more than 1018 nitrogen atoms per cm3 are present inside the second substrate, in particular due to doping. Doping is preferably carried out during growth of the second substrate, in particular by adding nitrogen and/or ammonium into a reaction chamber of used CVD reactor. B. Jayant Baliga disclosed in Wide Bandgap Semiconductor Power Devices; Materials, Physics, Design, and Applications; A volume in Woodhead Publishing Series in Electronic and Optical Materials; Book; 2019; ISBN: 978-0-08-102306-8 that the specific electrical resistance can be affected by doping, in particular nitrogen doping.

This solution is beneficial since the second substrate is at least partially radially grown, in particular by means of a CVD process. Such a CVD process is e.g., described in: Patent application EP22173970.9, filed May 18, 2022 with the European Patent Office. The subject-matter of EP22173970.9 is entirely incorporated by reference. Thus, the growth starting surface extends in more than two-dimensions respectively surrounds or covers a three-dimensional structure. Growing large SiC ingots by means of a CVD process allows removing a plurality of polycrystalline SiC wafers in a very cost-effective manner. Thus, the radially grown second substrate can be produced much cheaper compared to conventional epitaxy processes. Furthermore, since no homogeneous crystallite orientation is present in a radially grown polycrystalline SiC wafer tensions causing bow and/or warp are compensated by means of the heterogeneous crystallite orientation. Therefore, less post processing steps are required respectively the resulting polycrystalline SiC wafer (second substrate) can be produced even cheaper.

However, a preferred method for producing the second substrate or at least one second substrate, wherein the second substrate can be a SIC carrier wafer, in particular crack-free SiC carrier wafer, preferably comprises the step: Providing a CVD reactor, wherein the CVD reactor comprises at least one SiC growth substrate, wherein the at least one SiC growth substrate comprises a main body, a first power connection and a second power connection, wherein the main body has a main body length, wherein the main body length extends between the first power connection and the second power connection, wherein the first power connection is configured to conduct power into the main body for heating the main body and wherein the second power connection is configured to conduct electric power conducted via the first power connection into the main body out of the main body, wherein the main body forms a physical structure, wherein the physical structure forms a deposition surface for deposition of SiC. The method for producing the second substrate or at least one second substrate also comprises the step of growing a SiC solid by depositing SiC on the physical structure in the CVD reactor and the step of preferably mechanically removing, in particular by means of sawing, the at least one SiC piece from the SiC solid, and the step of preferably mechanically removing the at least one SiC carrier wafer from the SiC piece, in particular by means of sawing.

The method for producing the second substrate or at least one second substrate explains a preferred production method for producing the second substrate or at least one second substrate and can be subject-matter of an independent claim, in particular without further dependencies to the before described composite wafer or multi-substrate wafer.

The method for producing the second substrate or at least one second substrate preferably also comprises the step of processing the carrier wafer to reduce surface roughness of a surface of the SiC carrier wafer, wherein the surface is materialized or exposed by the step of mechanically removing the SiC carrier wafer from the SiC solid.

The method for producing the second substrate or at least one second substrate preferably also comprises the step of analyzing the SiC solid to determine a crack-free section of the SiC solid, wherein the step of analyzing the SiC solid is carried out prior to the step of mechanically removing, in particular by means of sawing, the at least one SiC piece from the SiC solid.

According to a further preferred aspect of the method for producing the second substrate or at least one second substrate the at least one SiC piece is removed from the crack-free section of the SiC solid or wherein the crack-free section of the SiC solid is removed as the at least one SiC piece.

According to a further preferred aspect of the method for producing the second substrate or at least one second substrate the step of analyzing the SiC solid to determine a crack-free section of the SiC solid is carried out by optical inspection, in particular by means of a caliper or threshold detection.

The method for producing the second substrate or at least one second substrate preferably also comprises the step of analyzing the SiC piece or the SiC carrier wafer to determine defects, in particular cracks. The step of analyzing the SiC piece or the SiC carrier wafer to determine defects is preferably carried out by means of a bend test, in particular a 2-point bend test, a 3-point bend test or a 4-point bend test, an eddy current testing and/or optical analyzing methods, in particular caliper testing or threshold testing or transmission testing.

According to a further preferred aspect of the method for producing the second substrate or at least one second substrate the step of heating the physical structure is carried out by conducting electric power from the first power connection to the second power connection or from the second power connection to the first power connection, wherein AC voltage is applied.

According to a further preferred aspect of the method for producing the second substrate or at least one second substrate the frequency of the AC voltage is preferably 1 Hz or above 1 Hz and preferably above 5 Hz or above 20 Hz or above 50 Hz or above 100 Hz or above 500 Hz or up to 5000 Hz, in particular up to 2000 Hz or up to 1000 Hz or up to 500 kHz. Thus, the range between 50 Hz and 500 kHz is highly preferred. The frequency can be varied during SiC is deposited, e.g. at the beginning of SiC depositing the frequencies can be lower compared to a later stage when the amount of deposited SiC is increased compared to the beginning. This is beneficial, since due to the AC voltage the electric power is guided along the outer surface of the growing SiC and therefore heats the center less compared to DC. This is beneficial since the temperature in the center is preferably below the temperature of the outer surface. This is highly beneficial to cause a homogeneous temperature profile between the center and the outer surface, thus the temperature difference between the outer surface and the center is preferably below 200K and more preferably below 100K and most preferably below 50K. This is beneficial to grow the SiC with a low level of tensions to avoid cracking of the SiC.

According to a further preferred aspect of the method for producing the second substrate or at least one second substrate the deposited SiC has a minimal thickness of at least 1 cm and wherein the at least one SiC piece is formed between a first plane and a second plane, and wherein the first plane is perpendicular to the main body length and wherein the second plane is perpendicular to the main body length, wherein the distance between the first plane and the second plane is at least 1% and preferably at least 2% and highly preferably at least 5% of the main body length, and wherein the deposited SiC is polycrystalline SiC, wherein the deposited SiC forms volume sections with different crystal structures, wherein a 3C crystal structure is predominantly (mass and/or volume) formed, wherein the volume and/or mass of SiC formed in the 3C crystal structure comprises more than 50% (volume and/or mass) of the deposited SiC, wherein the SiC carrier wafer is crack-free.

According to a further preferred aspect of the method for producing the second substrate or at least one second substrate the at least one SiC piece has a cross-sectional size of at least 4 cm2 and preferably of at least 8 cm2 and highly preferably of at least 12 cm2 and a thickness of at least 0,1 cm and preferably of at least 1 cm and highly preferably of at least 2 cm, and/or wherein the volume of the at least one SiC piece is more than 2 cm3 and preferably more than 4 cm3 and most preferably more than 8 cm3, wherein the at least one SiC piece is crack-free.

The method for producing the second substrate or at least one second substrate explains a preferred production method for producing the second substrate or at least one second substrate and can be subject-matter of an independent claim, in particular without further dependencies to the before described composite wafer or multi-substrate wafer.

Further preferred embodiments of the present invention are described in the following specification sections and/or by the dependent claims.

According to a preferred embodiment of the present invention the monocrystalline SiC crystal is formed by a crystal structure, wherein the crystal structure defines a c-axis, wherein the crystal structure is grown perpendicular to the c-axis, wherein the monocrystalline SiC crystal has a preferably flat top surface, a preferably flat bottom surface and a connecting-surface connecting the top surface and bottom surface, wherein the c-axis is aligned in an angle between 0° and 8° and preferably in an angle between 2° and 6° with respect to a normal on the top surface, wherein the monocrystalline SiC crystal consists of SiC of the 4H type. The distance between the flat bottom surface and the flat top surface of the thin substrate layer is preferably below 20 μm. This embodiment is beneficial since due to the growth direction perpendicular to the c-axis the number of screw dislocations is significantly reduced. According to a further preferred embodiment of the present invention the number of screw dislocations per cm3 present inside the monocrystalline SiC crystal is below the number of basal plane dislocations per cm3.

The top surface and bottom surface are considered to be “flat” since each surface has a Ra of less than 1 μm and preferably less than 100 nm and highly preferably less than 10 nm and most preferably less than 1 nm.

The top surface and the bottom surface are considered to be “parallel” since a virtual plane extending through the at least three highest peaks of the bottom surface is inclined less than 1° and preferably less than 0,1° and highly preferably less than 0,01°and most preferably less than 0,001° to a virtual plane extending through the at least three highest peaks of the top surface. The term “peaks” herewith refer to surface roughness and describes the distance from a mean line as used to calculate the arithmetic average of profile height deviations from the mean line (cf. Ra calculation; https://en.wikipedia.org/wiki/Surface_roughness; Mar. 27, 2023).

Production of a monocrystalline SiC crystal, which is formed by a crystal structure, wherein the crystal structure defines a c-axis, wherein the crystal structure is grown perpendicular to the c-axis is previously described by patent application EP22174029.3, filed May 18, 2022 with the European Patent Office. The subject-matter of EP22174029.3 is entirely incorporated by reference.

However, a preferred method for producing the first substrate preferably comprises the following steps:
increasing the at least one SiC crystal in a direction perpendicular to the axial direction of the SiC crystal, in particular one or multiple wafers or one or multiple boules, using a PVT reactor according to one of the claims 1-8 and
at least comprising the step:
Providing at least one SiC seed, in particular a seed boule or a seed wafer or a seed structure, having a top surface, a bottom surface and a connecting-surface connecting the top surface and bottom surface in a first configuration inside the PVT reactor, wherein the SiC seed is formed by a monocrystalline SiC crystal with a defined c-axis orientation. The method for producing the first substrate preferably also comprises the step of vaporizing source material provided in the source material receiving space.

The method for producing the first substrate preferably also comprises the step of growing the SiC crystal in the direction perpendicular to the defined c-axis orientation for transferring the SiC crystal in a second configuration, wherein monocrystalline mass accumulation on the connecting-surface of the SiC crystal is higher compared to monocrystalline mass accumulation on the top surface and/or a bottom surface of the SiC crystal.

The top surface and/or the bottom surface and/or the connecting-surface preferably has a surface roughness of Ra<20 nm.

The top surface and/or the bottom surface are preferably processed, in particular grinded and/or lapped and/or etched, after the step of growing to form two parallel surfaces.

The crystal lattice of the SiC crystal is preferably orientated in an off-angle of less than 10° and preferably of less than 9°and highly preferably of less than 5° and most preferably of less than 1° or the crystal lattice of the SiC crystal is preferably orientated in an off-angle of 0° or 4° or 8°.

The method for producing the first substrate or at least one first substrate explains a preferred production method for producing the first substrate or at least one first substrate and can be subject-matter of an independent claim, in particular without further dependencies to the before described composite wafer or multi-substrate wafer.

According to a further preferred embodiment of the present invention the second substrate forms a preferably flat top surface, a preferably flat bottom surface and a connecting-surface connecting the top surface and bottom surface and wherein the preferably flat top surface, the preferably flat bottom surface and the connecting-surface surround a polycrystalline structure, in particular formed by the grow, in particular radially grown, polycrystalline 3C—SiC. This embodiment is beneficial since the second substrate can be used as carrier wafer.

The polycrystalline structure forms according to a further preferred embodiment of the present invention a plurality of band shaped or line shaped, in particular at least partially curved, in particular at least partially circular or at least partially arc shaped, and/or at least partially straight elements. Said plurality of band shaped or line shaped and/or at least partially straight elements are preferably visible on or via the bottom or top surface. Said plurality of band shaped or line shaped and/or at least partially straight elements preferably extend preferably in height direction of the second substrate and at least partially surrounding a center of the second substrate. Said plurality of band shaped or line shaped and/or at least partially straight elements are beneficial since they allow assignment of the individual second substrates to one ingot or boule. Additionally, or alternatively the plurality of band shaped or line shaped and/or at least partially straight elements allow an analysis of growth speed and composition of the grown polycrystalline structure. Said plurality of band shaped or line shaped and/or at least partially straight elements preferably result from variances of densities in the polycrystalline structure. According to a preferred embodiment the plurality of band shaped or line shaped and/or at least partially straight elements are generated by varying the gas supply during growth of the polycrystalline structure.

The plurality of line shaped, in particular at least partially curved, in particular at least partially circular or at least partially arc shaped, and/or at least partially straight elements is according to a further preferred embodiment of the present invention formed in a distance of at least 1 nm to the preferably flat top surface inside, the preferably flat bottom surface and the connecting-surface. This embodiment is beneficial since the plurality of line shaped, in particular at least partially curved, in particular at least partially circular or at least partially arc shaped, and/or at least partially straight elements can be easily captured by optical analysis tools.

At least one and preferably at least two curved, circular and/or arc-shaped and/or straight elements have according to a further preferred embodiment of the present invention a length in circumferential direction of the second substrate of at least 10 nm, in particular at least 20 nm or at least 50 nm or at least 100 nm or at least or up to 5000 nm, in particular up to 2000 nm or 1000 nm.

The polycrystalline structure comprises according to a further preferred embodiment of the present invention crystallites extending in length direction of the individual crystallite more than 5 μm, in particular more than 10 μm and preferably more than 20 μm. The length directions of more than 30%, in particular more than 50% and preferably more than 70%, of the crystallites, which extend more than 5 μm in the length direction of the individual crystallite, in particular more than 10 μm or more than 20 μm, are preferably aligned in an angle of less than 75°, in particular less than 60° or preferably less than 45° and most preferably less than 30°, to the radial direction of the polycrystalline structure, in particular in a section of the polycrystalline structure.

The radially direction of the polycrystalline structure is preferably determined for multiple sections of the polycrystalline structure, wherein each section comprises in the center the radial direction of the respective section, wherein the respective section has a width of less than 500 μm, in particular of less than 300 μm and preferably of less than 100 μm, wherein the alignment between the radial direction of the polycrystalline structure and the length direction of the individual crystallite which extends more than 5 μm, in particular more than 10 μm and preferably more than 20 μm, is limited to crystallites present in a respective section and the radial direction of the respective section.

The height of the second substrate is according to a further preferred embodiment of the present invention below 500 μm, in particular below 400 μm. This embodiment is beneficial since a higher number of second substrates can be divided from one ingot or boule compared to larger second substrates.

The crystal structure of the monocrystalline SiC crystal comprises according to a further preferred embodiment less than 99,9999% (ppm wt) and preferably less than 99,99999% (ppm wt) and highly preferably less than 99,999999% (ppm wt) and most preferably less than 99,999999% (ppm wt) of one, multiple or all of the following substances B (Bor), Al (Aluminum), P (Phosphor), Ti (Titan), V (Vanadium), Fe (Eisen), Ni (Nickel). This embodiment is beneficial since power devices or units used in power devices and logic devices or units used in logic devices having better efficiency factors can be produced on top of the monocrystalline SiC crystal.

The flat top surface of the polycrystalline SiC has a surface roughness of Ra<20 nm and preferably of Ra<10 nm and most preferably of Ra<5 nm, wherein the monocrystalline SiC crystal is bonded to the flat top surface of the polycrystalline SiC. The surface roughness of Ra<20 nm and preferably of Ra<10 nm and most preferably of Ra<5 nm is preferably generated by means of grinding and/or lapping and/or etching, wherein Ra is preferably reduced due to grinding and/or lapping and/or etching more than 30 nm, in particular more than 50 nm or more than 100 nm or more than 200 nm or more than 500 nm or more than 1000 nm or more than 2000 nm and/or up to 5000 nm or up to 10000 nm or up to 20000 nm.

A monocrystalline SiC crystal layer is provided according to a further embodiment of the present invention on the thin substrate layer, wherein the monocrystalline SiC crystal is grown by means of epitaxy. This embodiment is beneficial since device production can be carried out on and/or in that monocrystalline SiC crystal layer. The thin substrate layer is preferably less doped compared to the second substrate, in particular comprises less than 1/10 or preferably less than 1/100 or highly preferably less than 1/1000 of the doping per cm3 compared to the second substrate. The thin substrate layer preferably has a distance between the flat bottom surface and the flat top surface of the thin substrate layer between 0,01 μm and 1 μm respectively below 1 μm or preferably below 0,8 μm or highly preferably below 0,5 μm.

Alternatively, the thin substrate layer has a distance between the flat bottom surface and the flat top surface of the thin substrate layer between 1 μm and 15 μm and preferably between 5 μm and 12 μm. In this case the thin substrate layer is preferably doped to match with requirements for the production of electronic devices, e.g., like MOSFETs or SCHOTTKEY Diods, in and/or on the thin substrate layer. Preferred doping levels are 1015-1016 nitrogen atoms per cm3. The second substrate preferably acts as n+substrate and the thin substrate layer preferably acts as n-Drift Region. With respect to doping levels it is referred to: Kimoto, Tsunenobu, James A. Cooper; Fundamentals of silicon carbide technology: growth, characterization, devices and applications; 1963; ISBN 978-1-118-31352-7.

The present invention is also directed to a method for the production of a compound or composite wafer or multi-substrate wafer, in particular according to any of claims 1 to 12. Said method preferably comprises at least the step of providing a first substrate, wherein the first substrate is a monocrystalline SiC crystal, wherein the monocrystalline SiC crystal is formed by a crystal structure, wherein the crystal structure defines a c-axis, wherein the crystal structure is grown perpendicular to the c-axis, wherein the monocrystalline SiC crystal has a preferably flat top surface, a preferably flat bottom surface and a connecting-surface connecting the top surface and bottom surface, wherein the c-axis is aligned in an angle between 0° and 8° and preferably in an angle between 2° and 6° with respect to a normal on the top surface.

It is herewith also referred to the production of a monocrystalline SiC crystal, which is formed by a crystal structure, wherein the crystal structure defines a c-axis, wherein the crystal structure is grown perpendicular to the c-axis, which is previously described in the previously mentioned patent application EP22174029.3, filed May 18, 2022 with the European Patent Office and to a before described method for producing the first substrate.

The method also comprises the step of providing a second substrate, wherein the second substrate consists of SiC, in particular polycrystalline 3C—SiC, wherein the at least 60% [volume] of the SiC, in particular polycrystalline SiC, is grown in radial direction, wherein the second substrate has a specific electrical resistance of less than 15 mOhmcm, in particular of less than 10 mOhmcm or preferably less than 5 mOhmcm or most preferably less than 3 mOhmcm.

It is herewith also referred to the production of a second substrate, which is at least partially radially grown, in particular by means of a CVD process. Such a CVD process is e.g., described in: Patent application EP22173970.9, filed May 18, 2022 with the European Patent Office.

The method additionally comprises the step of bonding the first substrate and the second substrate together. The flat bottom surface of the monocrystalline SiC crystal is preferably bonded to a flat top surface of the second substrate. This method is beneficial since a composite wafer is provided which can be produced at low cost and which provided a high-quality growth face for further processing, in particular epitaxial methods. The high-quality growth face is hereby materialized a surface of the monocrystalline SiC crystal, in particular by a surface opposite respectively parallel to the surface which is bonded to the second substrate.

According to a further preferred embodiment of the present invention the method also comprises the step of transforming the first substrate in a thin substrate layer by reducing the thickness of the first substrate to less than 20 μm, in particular less than 10 μm or less than 5 μm or less than 2 μm or less than 1 μm. This embodiment is beneficial since very little monocrystalline SiC crystal can be used. The production of monocrystalline SiC crystal generally causes high costs, thus reducing the necessary amount of monocrystalline SiC crystal reduces the overall costs.

The step of reducing the thickness of the first substrate to less than 20 μm is carried out according to a further preferred embodiment of the present invention after the first and second substrate are bonded together. This embodiment is beneficial since the resulting thin layer of monocrystalline SiC crystal is always supported by a solid structure.

A step of implanting ions into to the first substrate via the surface of the first substrate which is bonded to the second substrate before the first substrate and the second substrate are bonded together for defining a crack-plane inside the first substrate is carried out according to a further preferred embodiment of the present invention. This embodiment is beneficial since the ions can be implanted via the bottom surface of the monocrystalline SiC crystal before the bottom surface of the monocrystalline SiC crystal is bonded to the second substrate. Ion implantation is generally not possible deep inside a monocrystalline SiC crystal. Thus, due to implanting the ions via the bottom surface the monocrystalline SiC crystal can have a thickness of more than 50 μm and preferably of more than 100 μm and highly preferably of more than 200 μm prior to the reduction of the thickness.

A step of heating at least the implanted ions to a temperature above 800° C., in particular to a temperature between 850° C. and 1200° C., is carried out according to a further preferred embodiment of the present invention after the first substrate and the second substrate are bonded together for splitting the first substrate along the defined crack-plane into at least two pieces, wherein one piece is the thin substrate layer. This embodiment is beneficial since the remaining monocrystalline SiC crystal, which is divided from the thin substrate layer, can preferably be used multiple times for dividing thin substrate layers therefrom.

The step of bonding the first substrate and the second substrate together is carried out according to a further preferred embodiment of the present invention by means of plasma bonding or argon beam bonding. This embodiment is beneficial since such bonding processes are well known and easy to handle.

According to a further preferred embodiment of the present invention a step of growing a monocrystalline SiC layer by means of epitaxy onto the thin substrate layer is carried out, wherein monocrystalline SiC layer has a thickness between 1 μm and 50 μm, in particular between 2 μm and 40 μm or between 3 μm and 30 μm or between 4 μm and 20 μm or between 5 μm and 10 μm. This embodiment is beneficial since the compound or composite wafer according to the present invention can be integrated into an electronic device production process.

According to a preferred embodiment of the present invention the thin substrate layer has a thickness of less than 1 μm, wherein the c-axis is preferably aligned in an angle of 4°. Permissible deviation of the angle is 0,5° or less than 0,5° preferably 0,2° or less than 0,2° and most preferably 0,1° or less than 0,1°.

According to a preferred embodiment of the present invention a monocrystalline SiC crystal layer is provided on the thin substrate layer, wherein the monocrystalline SiC crystal is grown by means of epitaxy.

According to a preferred embodiment of the present invention the thin substrate layer has a thickness between 2 μm and 20 μm, in particular between 5 μm and 12 μm, and wherein the thin substrate layer comprises 1015-1016 nitrogen atoms per cm3, wherein the c-axis is preferably aligned in an angle of 0°. Permissible deviation of the angle is 0,5° or less than 0,5° preferably 0,2° or less than 0,2° and most preferably 0,1° or less than 0,1°.

The present invention also refers to an electronic device, in particular according to claim 21. The electronic device preferably comprises at least a multi-substrate wafer according to claim 13, wherein at least one electronic component is grown or produced on or in the monocrystalline SiC crystal layer, which is grown by epitaxy, and wherein the second substrate has a thickness of more than 50 μm, in particular more than 60 μm or more than 80 μm or more than 100 μm or more than 150 μm or up to 350. The electronic device can be a MOSFET or a Schottky Diode. This solution is beneficial since said electronic device can be produced at lower costs and higher quality.

The present invention also refers to an electronic device, in particular according to claim 22. The electronic device preferably comprises at least a multi-substrate wafer according to claim 14, wherein at least one electronic component is grown or produced on or in the thin substrate layer and wherein the second substrate has a thickness of more than 50 μm, in particular more than 60 μm or more than 80 μm or more than 100 μm or more than 150 μm or up to 350.

The present invention can also refer to a multi-substrate wafer, at least comprising a first substrate and a second substrate, wherein the first substrate and the second substrate are bonded together, wherein the first substrate is a monocrystalline SiC crystal, wherein the monocrystalline SiC crystal is formed by a crystal structure, wherein the crystal structure defines a c-axis, wherein the crystal structure is grown perpendicular to the c-axis, wherein the monocrystalline SiC crystal has a preferably flat top surface, a preferably flat bottom surface and a connecting-surface connecting the top surface and bottom surface, wherein the c-axis is aligned in an angle between 0° and 8° and preferably in an angle between 2° and 6° with respect to a normal on the top surface, wherein the second substrate consists of polycrystalline SiC.

Further advantages, objectives and features of the present invention are explained with reference to the following description of accompanying drawings, in which the device(s) according to the invention are shown by way of example. Components or elements of the composite wafer or method according to the invention, which at least substantially correspond in the figures with respect to their function, can be marked with the same reference signs, whereby these components or elements do not have to be numbered or explained in all figures.

### BRIEF DESCRIPTION OF THE FIGURES

FIG. 1a shows a step of the production of a composite wafer according to the present invention;

FIG. 1b shows a step of the production of a composite wafer according to the present invention;

FIG. 1c shows a step of the production of a composite wafer according to the present invention;

FIG. 1d shows a step of the production of a composite wafer according to the present invention;

FIG. 1e further shows an optional further step of growing an epi-layer on the composite wafer;

FIG. 2a shows a similar method compared to FIGS. 1a-d, wherein the thin substrate layer is thicker compared to FIG. 1a-d to provide a composite wafer that can be used for device production without an epi-layer production step;

FIG. 2b shows a similar method compared to FIGS. 1a-d, wherein the thin substrate layer is thicker compared to FIG. 1a-d to provide a composite wafer that can be used for device production without an epi-layer production step;

FIG. 2c shows a similar method compared to FIGS. 1a-d, wherein the thin substrate layer is thicker compared to FIG. 1a-d to provide a composite wafer that can be used for device production without an epi-layer production step;

FIG. 2d shows a similar method compared to FIGS. 1a-d, wherein the thin substrate layer is thicker compared to FIG. 1a-d to provide a composite wafer that can be used for device production without an epi-layer production step;

FIG. 3 shows a high-resolution photo of the crystal structure of the second substrate, FIG. 4 shows FIG. 3 with modifications indicating the main growth direction (radial direction) as well as multiple orientations of large crystallites;

FIG. 5a shows a conventional growth of a carrier wafer;

FIG. 5b shows the growth direction in specific sections;

FIG. 5c shows the growth direction in specific sections;

FIG. 5d shows the growth direction in specific sections;

FIG. 6 shows an enlarged section of FIG. 3, wherein the length direction and boundary of one crystallite is highlighted;

FIG. 7a shows line shaped elements generated during the growth process; and

FIG. 7b shows line shaped elements generated during the growth process.

### DETAILED DESCRIPTION

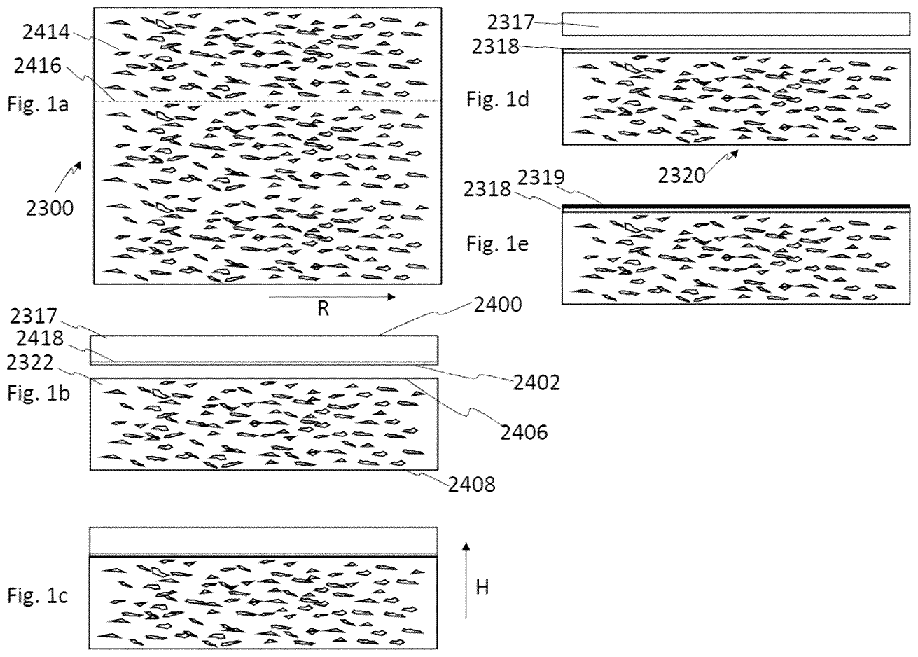

FIG. 1a shows a polycrystalline SiC piece 2300, in particular an ingot or boule. Reference number 2414 schematically refers to a crystallite at least mainly orientated into radial direction (R). Line 2416 schematically illustrates a dividing plane along which the SiC Piece 2300 is divided in two pieces. In the shown example the smaller section of the SiC piece 2300 respectively the section above line 2416 forms a “second substrate” 2322 according to the present invention respectively a carrier wafer 2322.
FIG. 1b shows a first substrate 2317 and a second substrate 2322 according to the present invention. The first substrate 2322 is preferably a monocrystalline SiC crystal and the second substrate is preferably a polycrystalline SiC structure, wherein the first substrate 2317 and the second substrate 2322 are both at least partially (vol.) and preferably mainly (vol.) or most preferably entirely grown in radial direction.

The first substrate 2317 preferably comprises ions arranged on a layer 2418 for dividing a thin substrate layer 2318 from the first substrate 2317. The ions can be expanded during a later heating process and locally cause the crystal structure to crack and thereby divide the first substrate 2317 into to pieces. Such a dividing is known as “Smart-Cut-Process”.

FIG. 1c shows the first substrate 2317 and the second substrate 2322 bonded together. Arrow “H” indicates the height direction respectively the direction in which the top surface of second substrate 2406 and bottom surface of second substrate 2408 are arranged in a distance to each other as well as the top surface of first substrate 2400 and bottom surface of first substrate 2402 are arranged in a distance to each other.

FIG. 1d shows the composite wafer 2320 of the present invention after the step of dividing the thin substrate layer 2318 from the first substrate 2317.

FIG. 1e shows an optional step of growing an epi-layer 2319 on top of the thin substrate layer 2318.

The epi-layer 2319 is a monocrystalline SiC crystal layer 2319 which is produced on the thin substrate layer 2318, wherein the monocrystalline SiC crystal layer 2319 is grown by means of epitaxy and wherein the thin substrate layer 2318 has a thickness of less than 1 μm and wherein the monocrystalline SiC crystal layer 2319 preferably has a thickness of 0,5 μm to 20 μm, in particular of 1 μm to 15 μm or 1 μm to 12 μm or preferably 2 μm to 15 μm or 2 μm to 12 μm.

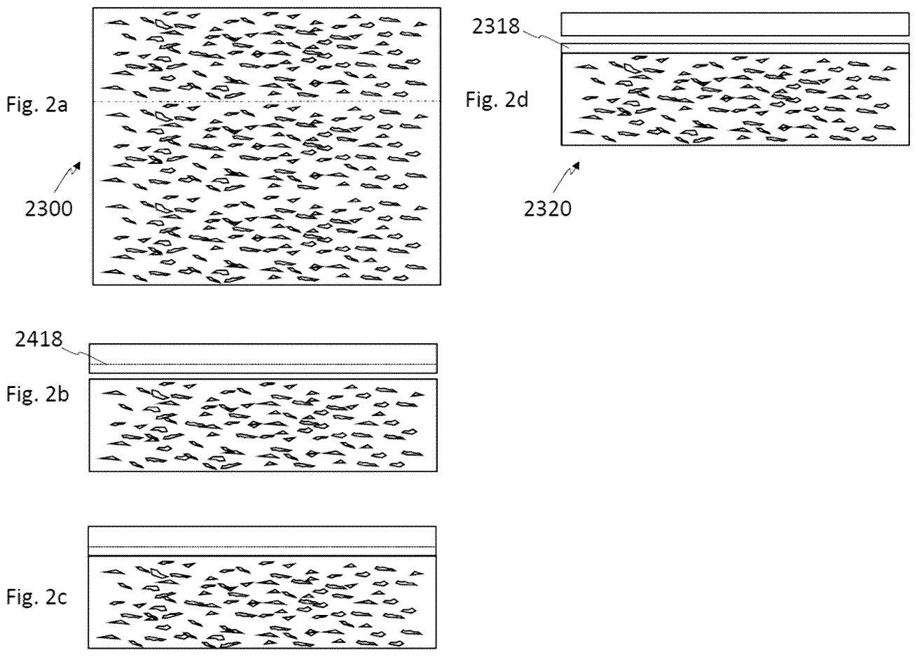

Thus, in view of FIG. 1a-d and FIG. 2a-d the method for the production of a compound respectively composite wafer respectively or multi-substrate wafer 2320 according to the present invention preferably comprises the steps of providing a first substrate, providing a second substrate 2322 and bonding the first substrate 2317 and the second substrate 2322 together. The first substrate 2317 is preferably a monocrystalline SiC crystal, wherein the monocrystalline SiC crystal 2317 is formed by a crystal structure, wherein the crystal structure defines a c-axis, wherein the crystal structure is grown perpendicular to the c-axis, wherein the monocrystalline SiC crystal 2317 has a preferably flat top surface 2400, a preferably flat bottom surface 2402 and a connecting-surface 2404 connecting the top surface 2400 and bottom surface 2402, wherein the c-axis is aligned in an angle between 0° and 8° and preferably in an angle between 2° and 6° with respect to a normal on the top surface 2400. The second substrate 2322 preferably comprises or consists of polycrystalline SiC, in particular 3C—SiC, wherein the at least 60% [volume] of the polycrystalline SiC is grown in radial direction, wherein the second substrate 2322 has a specific electrical resistance of less than 15 mOhmcm, bonding the first substrate 2317 and the second substrate 2322 together.

The method preferably also comprises the step of transforming the first substrate 2317 in a thin substrate layer 2318 by reducing the thickness of the first substrate 2317 to less than 20 μm, wherein the step of reducing the thickness of the first substrate 2317 to less than 20 μm is carried out after the first and second substrate 2322 are bonded together.

Thus, the present invention refers to a multi-substrate wafer 2320. Said multi-substrate wafer 2320 comprises at least a first substrate 2317 and a second substrate, wherein the first substrate 2317 and the second substrate 2322 are bonded together, wherein the first substrate 2317 is a monocrystalline SiC crystal 2317, wherein the second substrate 2322 comprises polycrystalline 3C—SiC, wherein the at least 30% [volume], in particular at least 50% [volume] and preferably at least 70% [volume], of the polycrystalline 3C—SiC is grown in radial direction around at least one or exactly one central element 857, wherein the central element 857 preferably comprises or consists of SiC, wherein the second substrate 2322 has a specific electrical resistance of less than 15 mOhmcm, wherein the second substrate 2322 is at least nitrogen doped, wherein more than 1018 nitrogen atoms per cm3 are present inside the second substrate 2322 due to doping.

FIG. 2a corresponds to FIG. 1a.

FIG. 2b shows the first substrate 2317 comprising an ion layer 2418 for removing the thin layer 2318, wherein the ion layer 2418 is arranged in a larger distance compared to FIG. 1b.

FIG. 2 a-d show that the thin substrate layer 2318 preferably has a thickness between 2 μm and 20 μm, in particular between 5 μm and 12 μm, and wherein the thin substrate layer 2318 highly preferably comprises 1015-1016 nitrogen atoms per cm3. Thus, the substrate layer 2318 can act as n-Drift region and the second substrate can act as n+substrate in case of an electric device, like e.g., a SCHOTTKEY Diode.

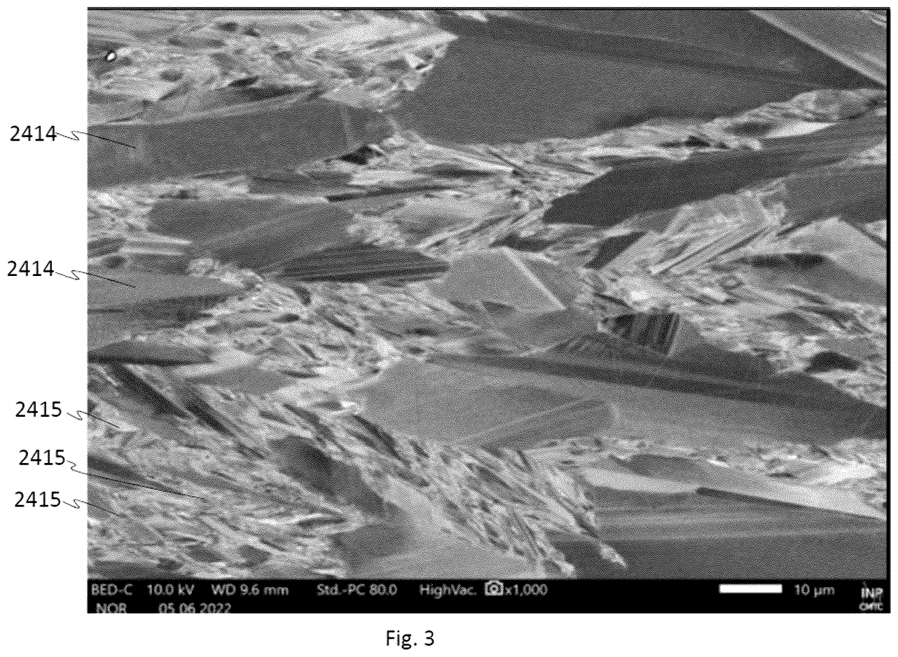

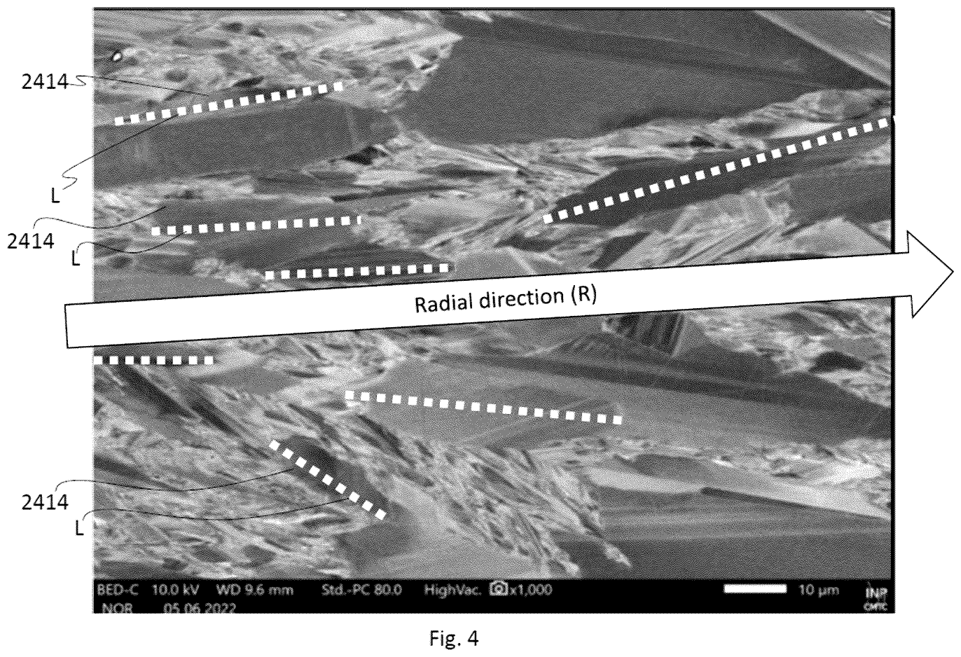

FIG. 3 show a high-resolution photo of a section of a second substrate 2322. Reference numbers 2414 refer to crystallites having a length extension of more than 5 μm and refence numbers 2415 refer to crystallites having a length extension of less than 5 μm.

FIG. 4 shows a modified version of FIG. 3. Multiple large crystallites 2414 are identified and the length direction of said large crystallites 2414 is indicated by dotted lines. An overall radial direction R indicates the direction of expansion of the polycrystalline SiC during growth.

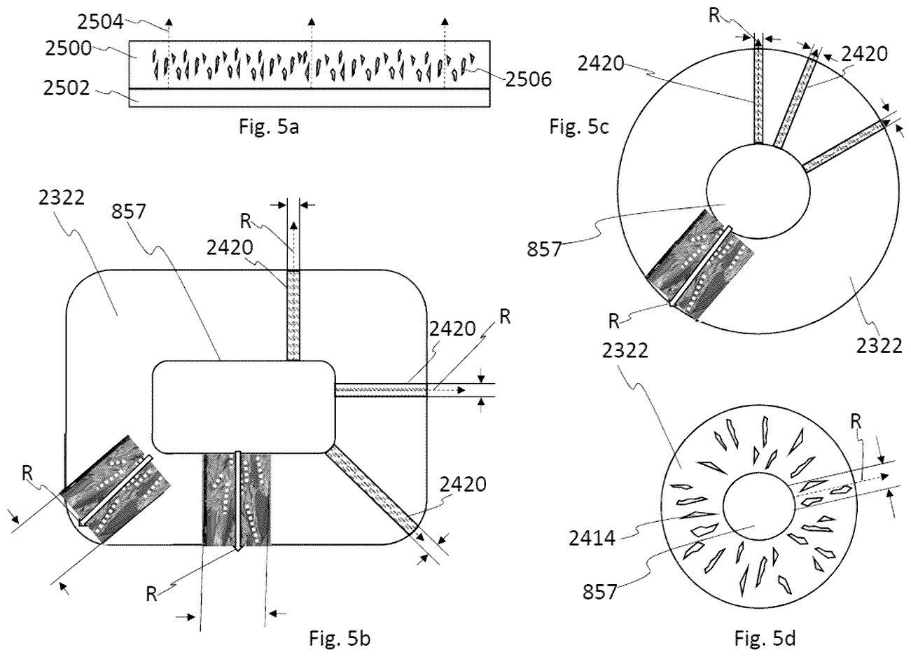

FIG. 5a shows a state-of-the-art carrier wafer 2500. Said carrier wafer 2500 is grown by means of epitaxy in a flat growth substrate 2502. The growth direction 2504 is only in one direction respectively orthogonal to the plane surface of growth substrate 2502. FIG. 5a also schematically shows that the length direction of the plurality of large crystallites 2506 is mainly orientated in one direction.

FIG. 5b shows that a central element respectively growth substrate 857 provides a growth face extending in 3D space and therefore not only in 2D space as shown in FIG. 5 b.

FIGS. 5b and 5c/d show that the central element/SiC growth substrate 857 can have multiple shapes.

With respect to FIGS. 5b, 5c and 5d it has to be understood that “radial” does not only apply in cases, in which the central element/SiC growth substrate 857 has a circular shape (cross-sectional) respectively in cases in which a “radius” is present. “Radial” describes in the context of the present invention the growth direction during expanding of the polycrystalline structure, along a lateral surface respectively growth face. Thus, the radial direction R of the polycrystalline structure 2322 can be preferably determined for multiple sections of the polycrystalline structure 2322, wherein each section 2420 preferably comprises in its center the radial direction R of the respective section 2420, wherein the respective section 2420 preferably has a width of less than 500 μm, in particular of less than 300 μm and preferably of less than 100 μm, wherein the alignment between the radial direction R of the polycrystalline structure 2322 and the length direction L of the individual crystallite 2414 which extends more than 5 μm, in particular more than 10 μm and preferably more than 20 μm, is limited to crystallites 2414 present in a respective section 2420 and the radial direction R of the respective section 2420.

The central element/SiC growth substrate 857 is preferably also grown in radial direction, in particularly removed from a radially grown section of a SiC piece 2300, in particular ingot or boule.

FIG. 5d schematically shows that the orientation of the large crystallites 2414 changes in circumferential direction of the polycrystalline crystal structure 2322.

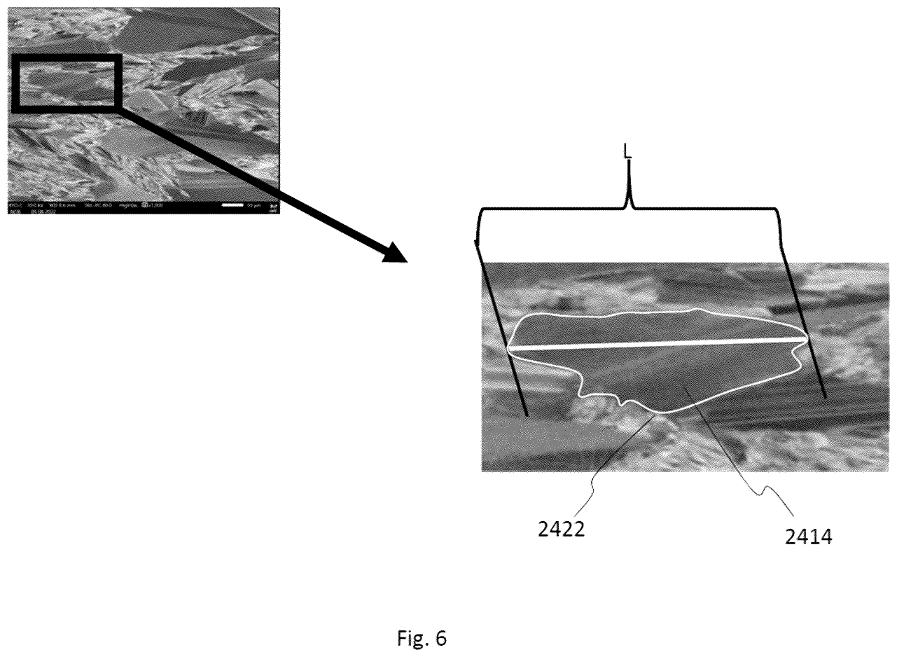

FIG. 6 shows an enlarged section of FIG. 3. Said section shows a crystallite 2414, wherein the boundary 2422 of said crystallite 2414 is marked with a thin white line. A straight white line connects two points of the crystallite 2414 which are arranged in the largest distance to each other. Thus, the white line represents the length direction of the crystallite 2414. Said definition of the length direction L of the crystallite 2414 is used with respect to all embodiments of the present invention.

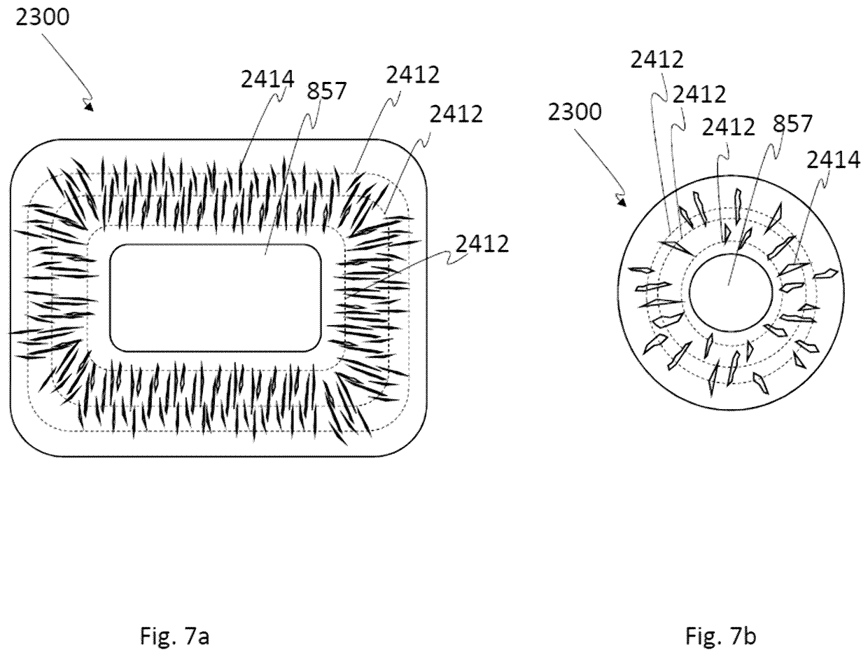

FIGS. 7a and 7b schematically show that band shaped or line shaped or straight elements 2412 representing growth rings or growth lines are present in the grown SiC piece 2300. The plurality of line shaped, in particular at least partially curved, in particular at least partially circular or at least partially arc shaped, and/or at least partially straight elements 2412 is preferably formed in a distance of at least 1 nm to the preferably flat top surface 2406 inside, the preferably flat bottom surface 2408 and the connecting-surface 2410.

At least one and preferably at least two curved, circular, straight and/or arc-shaped elements 2412 have at least a length in circumferential direction of the second substrate 2322 of at least 10 nm, in particular at least 20 nm or 50 nm or 100 nm. Preferably are at least one or two curved, circular, straight and/or arc-shaped elements 2412 extending entirely around the central element/SiC growth substrate 857.

### List of Reference Numbers

857 central element/SiC growth substrate
2300 SiC piece
2317 first substrate/monocrystalline SiC crystal
2318 thin substrate layer
2319 epi-layer
2320 multi-substrate wafer/composite substrate
2322 second substrate/carrier wafer/polycrystalline SiC structure
2400 top surface of first substrate
2402 bottom surface of first substrate
2404 connecting-surface of first substrate
2406 top surface of second substrate
2408 bottom surface of second substrate
2410 connecting-surface of second substrate
2412 band shaped or line shaped or straight element
2414 large crystallite
2415 small crystallite
2416 cutting plane
2418 layer of implanted ions
2420 section
2500 state of the art carrier wafer
2502 growth substrate for epitaxial growth of a state-of-the-art carrier wafer
2504 growth direction of a state-of-the-art carrier wafer
2506 large crystallite of a state-of-the-art carrier wafer
H height direction
L length direction of a crystallite
R radial direction of the polycrystalline structure

1. A multi-substrate wafer, comprising a first substrate and a second substrate, wherein the first substrate and the second substrate are bonded together,
wherein the first substrate is a monocrystalline SiC crystal,
wherein the second substrate comprises polycrystalline 3C—SiC,
wherein at least 30% [volume]of the polycrystalline 3C—SiC is grown in a radial direction around a central element, wherein the central element comprises SiC,
wherein the second substrate has a specific electrical resistance of less than 30 mOhm-cm,
wherein the second substrate is nitrogen doped, wherein more than 10¹⁸ nitrogen atoms per cm³ are present inside the second substrate due to doping.

2. The multi-substrate wafer according to claim 1,
characterized in that
the monocrystalline SiC crystal is formed by a crystal structure, wherein the crystal structure defines a c-axis, wherein the crystal structure is grown perpendicular to the c-axis,
wherein the monocrystalline SiC crystal has a flat top surface, a flat bottom surface and a connecting-surface connecting the top surface and bottom surface,
wherein the c-axis is aligned in an angle between 0° and 8° and in an angle between 2° and 6° with respect to a normal on the flat top surface,
wherein the monocrystalline SiC crystal consists of SiC of the 4H type.

3. The multi-substrate wafer according to claim 2,
characterized in that
the second substrate forms a flat top surface, a flat bottom surface and a connecting-surface connecting the top surface and bottom surface and wherein the flat top surface, the flat bottom surface and the connecting-surface surround a polycrystalline structure formed by the radial grow polycrystalline 3C—SiC.

4. The multi-substrate wafer according to claim 3,
characterized in that
the polycrystalline structure forms a plurality of band shaped or line shaped and/or at least partially straight elements.

5. The multi-substrate wafer according to claim 4,
characterized in that
the plurality of line shaped and/or at least partially straight elements is formed in a distance of at least 1 nm to the flat top surface inside, the flat bottom surface and the connecting-surface.

6. The multi-substrate wafer according to claim 4,
characterized in that
at least one circular and/or arc-shaped elements have at least a length in circumferential direction of the second substrate of at least 10 nm.

7. The multi-substrate wafer according to claim 3,
characterized in that
the polycrystalline structure comprises crystallites extending in length direction of the individual crystallite more than 5 μm,
wherein the length directions of more than 30% of the crystallites, which extend more than 5 μm in the length direction of the individual crystallite are aligned in an angle of less than 75°to the radial direction of the polycrystalline structure.

8. The multi-substrate wafer according to claim 3,
characterized in that
the height of the second substrate is below 500 μm.

9. The multi-substrate wafer according to claim 3,
characterized in that
the crystal structure of the monocrystalline SiC crystal comprises less than 99,9999% (ppm wt) of one, multiple or all of the following substances B (Bor), Al (Aluminum), P (Phosphor), Ti (Titan), V (Vanadium), Fe (Eisen), Ni (Nickel).

10. The multi-substrate wafer according to claim 3,
characterized in that
the flat top surface of the polycrystalline 3C—SiC has a surface roughness of Ra<20 nm, wherein the monocrystalline SiC crystal is bonded to the flat top surface of the polycrystalline 3C—SiC.

11. The multi-substrate wafer according to claim 2,
characterized in that
the number of screw dislocations present inside the monocrystalline SiC crystal is below number of basal plane dislocations.

12. The multi-substrate wafer according to claim 2,
characterized in that
the thin substrate layer has a thickness of less than 1 μm, wherein the c-axis is aligned in an angle of 4°.

13. The multi-substrate wafer according to claim 12,
characterized in that
a monocrystalline SiC crystal layer is provided on the thin substrate layer, wherein the monocrystalline SiC crystal is grown by means of epitaxy.

14. The multi-substrate wafer according to claim 2,
characterized in that
the thin substrate layer has a thickness between 2 μm and 20 μm, and wherein the thin substrate layer comprises 10¹⁵-10¹⁶ nitrogen atoms per cm³, wherein the c-axis is aligned in an angle of 0°.

15. A method for the production of a multi-substrate wafer, comprising the steps:
providing a first substrate
wherein the first substrate is a monocrystalline SiC crystal,
wherein the monocrystalline SiC crystal is formed by a crystal structure, wherein the crystal structure defines a c-axis, wherein the crystal structure is grown perpendicular to the c-axis,
wherein the monocrystalline SiC crystal has a flat top surface, a flat bottom surface and a connecting-surface connecting the top surface and bottom surface,
wherein the c-axis is aligned in an angle between 0° and 8° with respect to a normal on the top surface
providing a second substrate
wherein the second substrate consists of polycrystalline 3C—SiC,
wherein the at least 60% [volume] of the polycrystalline SiC is grown in radial direction,
wherein the second substrate has a specific electrical resistance of less than 15 mOhm-cm,
bonding the first substrate and the second substrate together.

16. The method according to claim 15,
characterized by
transforming the first substrate in a thin substrate layer by reducing the thickness of the first substrate to less than 20 μm.

17. The method according to claim 16,
characterized in that
the step of reducing the thickness of the first substrate to less than 20 μm is carried out after the first and second substrate are bonded together.

18. The method according to claim 17,
characterized by
implanting ions into to the first substrate via the surface of the first substrate which is bonded to the second substrate before the first substrate and the second substrate are bonded together for defining a crack-plane inside the first substrate and
heating at least the implanted ions to a temperature above 800° C. after the first substrate and the second substrate are bonded together for splitting the first substrate along the defined crack-plane into at least two pieces, wherein one piece is the thin substrate layer.

19. The method according to claim 15,
characterized in that
the step of bonding the first substrate and the second substrate together is carried out by means of plasma bonding or argon beam bonding.

20. The method according to claim 16,
characterized by
growing a monocrystalline SiC layer by means of epitaxy onto the thin substrate layer, wherein monocrystalline SiC layer has a thickness between 1 μm and 50 μm.

21. An electronic device
comprising
a multi-substrate wafer according to claim 13,
wherein at least one electronic component is grown or produced on or in the monocrystalline SiC crystal layer
and
wherein the second substrate has a thickness of more than
50 μm.

22. An electronic device
comprising
a multi-substrate wafer according to claim 14,
wherein at least one electronic component is grown or produced on or in the thin substrate layer
and
wherein the second substrate has a thickness of more than
50 μm.
